(19) United States
(12) Patent Application Publication
(10) Pub. No.: US 2007/0281108 A1
(43) Pub. Date: Dec. 6, 2007

(54) Process for Plasma Coating

(76) Inventors: Christopher M Weikart, Midland, MI (US); Todd D. Smith, Essexville, MI (US)

Correspondence Address: THE DOW CHEMICAL COMPANY, INTELLECTUAL PROPERTY SECTION, P. O. BOX 1967, MIDLAND, MI, 48641-1967, US

(21) Appl. No.: 11/662,379

(22) PCT Filed: Oct. 5, 2005
(86) PCT No.: PCT/US05/36160

§ 371 Date: Mar. 9, 2007

Related U.S. Application Data
(60) Provisional application No. 60/618,497, filed on Oct. 13, 2004.
(60) Provisional application No. 60/627,593, filed on Nov. 12, 2004.

(51) Int. Cl. C08J 7/04; C23C 16/04

(52) U.S. Cl. 427/575; 427/569

(57) ABSTRACT

The present invention describes a method for plasma coating the inside surface of a polyolefin or a polylactic acid container to provide an effective barrier against gas transmission. The method provides a way to deposit rapidly and uniformly very thin, adherent and nearly defect-free layers of polyorganosiloxane and silicon oxide (or amorphous carbon) on the inner surface of the container to achieve more than an order of magnitude increase in barrier properties.

### CROSS REFERENCE STATEMENT

This application claims the benefit of U.S. Provisional Application Nos. 60/618,497 and 60/627,593 filed Oct. 13, 2004 and Nov. 12, 2004, respectively.

### BACKGROUND

The present invention relates to a process for depositing a plasma-generated coating onto a container, more particularly onto the inside surface of a polyolefin or polylactic acid container.

Plastic containers have been used to package carbonated and non-carbonated beverages for many years. Plastics such as polyethylene terephthalate (PET) and polypropylene (PP) are preferred by consumers because they resist breakage, and they are light-weight and transparent. Unfortunately, the shelf-life of the beverage is limited in plastics due to relatively high oxygen and carbon dioxide permeability.

Efforts to treat plastic containers so as to impart low oxygen and carbon dioxide permeability are known. For example, Laurent et al. (WO 9917333) describes using plasma enhanced chemical vapor deposition (PECVD) to coat the inside surface of a plastic container with a SiOₓ layer. In general, SiOₓ coatings provide an effective barrier to gas transmission; nevertheless, SiOₓ is insufficient to form an effective barrier to gas transmission for plastic containers.

In U.S. Pat. No. 5,641,559, Namiki describes deposition of a plasma polymerized silicic compound onto the outer surface of PET and PP bottles, followed by deposition of a SiOx layer. The thickness of the polymerized silicic compound ranges from 0.01 to 0.1 micrometer and the thickness of the SiOₓ layer ranges from 0.03 to 0.2 micrometer. Although Namild discloses the combination of the plasma polymerized silicic compound and the SiOₓ layer (where x is 1.5 to 2.2), wherein the coating time of the layers is on the order of 15 minutes, which is impractical for commercial purposes. Moreover, the process described by Namild is disadvantaged because much of the plasma polymerized monomer is deposited in places other than the desired substrate. This undesired deposition results in inefficient precursor-to-coating conversion, contamination, equipment fouling, and non-uniformity of coating of the substrate.

United States Patent Application Publication 2004/0149225 A1 described an advanced process and apparatus for depositing a plasma coating onto a container. However, when the process and apparatus of United States Patent Application Publication 2004/0149225 A1 is used to coat polyolefin containers, the coating does not adhere to the polyolefin container as well as the coating adheres to a PET container.

It would, therefore, be desirable to discover an improved process for rapidly coating a polyolefin container (or a polylactic acid container) uniformly to provide an effective adherent barrier against gas transmission and to reduce contamination.

### SUMMARY OF THE INVENTION

The instant invention is a solution, at least in part, to the above stated problem of plasma coating polyolefin or polylactic acid containers. The instant invention is a method for plasma coating the inside surface of a polyolefin or polylactic acid container to provide an effective barrier against gas transmission. The method provides a way to deposit rapidly and uniformly very thin, adherent and nearly defect-free layers of polyorganosiloxane and silicon oxide (or amorphous carbon) on the inner surface of the container to achieve more than an order of magnitude increase in barrier properties.

More specifically, the instant invention is an improved process for preparing a protective barrier for a container including the step of plasma coating the interior of the container with a plasma polymerized coating, wherein the improvement comprises the step of pretreating the interior surface of a polyolefin or a polylactic acid container with a plasma for less than one minute.

In another embodiment, the instant invention is an improved process for preparing a protective barrier for a container including the step of plasma coating the interior of the container with a plasma induced coating of amorphous carbon, wherein the improvement comprises the step of treating the interior surface of the coated container with a plasma for less than one minute, the container being a polyolefin container or a polylactic acid container.

### BRIEF DESCRIPTION OF THE DRAWINGS

FIG. 1 is an illustration of an apparatus used to coat the inside of a container.

### DETAILED DESCRIPTION OF THE INVENTION

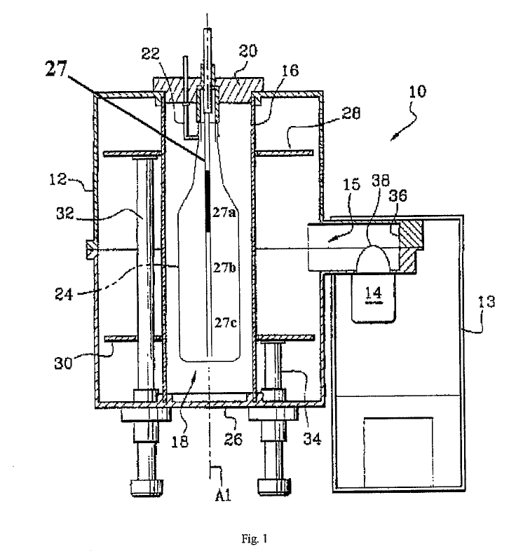

The process of the present invention is advantageously, though not uniquely, carried out using the apparatus described in WO0066804, which is reproduced with some modification in FIG. 1 and with specific regard to the polyorganosiloxane and silicon oxide coating process, the apparatus and method described in United States Patent Application Publication 2004/0149225 A1. The apparatus 10 has an external conducting resonant cavity 12, which is preferably cylindrical (also referred to as an external conducting resonant cylinder having a cavity). Apparatus 10 includes a generator 14 that is connected to the outside of resonant cavity 12. The generator 14 is capable of providing an electromagnetic field in the microwave region, more particularly, a field corresponding to a frequency of 2.45 GHz. Generator 14 is mounted on box 13 on the outside of resonant cavity 12 and the electromagnetic radiation it delivers is taken up to resonant cavity 12 by a wave guide 15 that is substantially perpendicular to axis Al and which extends along the radius of the resonant cavity 12 and emerges through a window located inside the resonant cavity 12.

Tube 16 is a hollow cylinder transparent to microwaves located inside resonant cavity 12. Tube 16 is closed on one end by a wall 26 and open on the other end to permit the introduction of a container 24 to be treated by PECVD. Container 24 is a container having at least an inner surface consisting essentially of polyolefin (such as polypropylene) or polylactic acid. It should be understood that the term “polyolefin” includes copolymers of an olefin (such as ethylene or propylene) copolymerized with another olefin (such as 1-octene).

The open end of tube 16 is then sealed with cover 20 so that a partial vacuum can be pulled on the space defined by tube 16 to create a reduced partial pressure on the inside of container 24. The container 24 is held in place at the neck by a holder 22 for container 24. Partial vacuum is advantageously applied to both the inside and the outside of container 24 to prevent container 24 from being subjected to too large a pressure differential, which could result in deformation of container 24. The partial vacuums of the inside and outside of the container are different, and the partial vacuum maintained on the outside of the container is set so as not to allow plasma formation onto the outside of container 24 where deposition is undesired. Preferably, a partial vacuum in the range of from about 20 μbar to about 200 μbar is maintained for the inside of container 24 and a partial vacuum of from about 20 mbar to about 100 mbar, or more than 10 μbar, is pulled on the outside of the container 24.

Cover 20 is adapted with an injector 27 that is fitted into container 24 so as to extend at least partially into container 27 to allow introduction of reactive fluid that contains a reactive monomer and a carrier. Injector 27 can be designed to be, for example, porous, open-ended, longitudinally reciprocating, rotating, coaxial, and combinations thereof. As used herein, the word “porous” is used in the traditional sense to mean containing pores, and also broadly refers to all gas transmission pathways, which may include one or more slits. A preferred embodiment of injector 27 is an open-ended porous injector, more preferably an open-ended injector with graded—that is, with different grades or degrees of—porosity, which injector extends preferably to almost the entire length of the container. The pore size of injector 27 preferably increases toward the base of container 24 so as to optimize flux uniformity of activated precursor gases on the inner surface of container 24. FIG. 1 illustrates this difference in porosity by different degrees of shading, which represent that the top third of the injector 27a has a lower porosity than the middle third of the injector 27b, which has a lower porosity than the bottom third of the injector 27c. The porosity of injector 27 generally ranges on the order of 0.5 μm to about 1 mm. However, the gradation can take a variety of forms from stepwise, as illustrated, to truly continuous. The cross-sectional diameter of injector 27 can vary from just less than the inner diameter of the narrowest portion of container 24 (generally from about 40 mm) to about 1 mm.

The apparatus 10 also includes at least one electrically conductive plate in the resonant cavity to tune the geometry of the resonant cavity to control the distribution of plasma in the interior of container 24. More preferably, though not essentially, as illustrated in FIG. 1, the apparatus 10 includes two annular conductive plates 28 and 30, which are located in resonant cavity 12 and encircle tube 16. Plates 28 and 30 are displaced from each other so that they are axially attached on both sides of the tube 16 through which the wave guide 15 empties into resonant cavity 12. Plates 28 and 30 are designed to adjust the electromagnetic field to ignite and sustain plasma during deposition. The position of plates 28 and 30 can be adjusted by sliding rods 32 and 34.

Pretreatment of the container 24 can be accomplished as follows. A pretreatment gas or a mixture of gases such as Ar, He, H₂, O₂, N₂, air, CF₄, C₂F₆, CO₂, H₂O, O₃, N₂O and NO is flowed through injector 27 at a flow rate in the range of 10 to 1000 sccm, at a pressure in the range of 13 to 1333 μbars, using a power in the range of 20 to 2000 watts for a time less than one minute. Preferably, the pretreatment gas is oxygen. Preferably, the flow rate of the pretreatment gas is less than 500 sccm. More preferably, the flow rate of the pretreatment gas is less than 100 sccm. Preferably, the pressure of the pretreatment gas in the container 24 is less than 666 μbars. More preferably, the pressure of the pretreatment gas in the container 24 is less than 133 μbars. Preferably, the pretreatment time is less than 20 seconds. More preferably, the pretreatment time is less than 2 seconds.

Deposition of polyorganosiloxane and SiOx layers on the pretreated container 24 can be accomplished as follows as described in United States Patent Application Publication 2004/0149225 A1. A mixture of gases including a balance gas and a working gas (together, the total gas mixture) is flowed through injector 27 at such a concentration and power density, and for such a time to create coatings with desired gas barrier properties.

As used herein, the term “working gas” refers to a reactive substance, which may or may not be gaseous at standard temperature and pressure, that is capable of polymerizing to form a coating onto the substrate. Examples of suitable working gases include organosilicon compounds such as silanes, siloxanes, and silazanes. Examples of silanes include tetramethylsilane, trimethylsilane, dimethylsilane, methylsilane, dimethoxydimethylsilane, methyltrimethoxysilane, tetramethoxysilane, methyltriethoxysilane, diethoxydimethylsilane, methyltriethoxysilane, triethoxyvinylsilane, tetraethoxysilane (also known as tetraethylorthosilicate or TEOS), dimethoxymethylphenylsilane, phenyltrimethoxysilane, 3-glycidoxypropyltrimethoxysilane, glycidoxypropyltrimethoxysilane, 3-methacrylpropyltrimethoxysilane, diethoxymethylphenylsilane, tris(2-methoxyethoxy)vinylsilane, phenyltriethoxysilane, and dimethoxydiphenylsilane. Examples of siloxanes include tetramethyldisiloxane, hexamethyldisiloxane, and octamethyltrisiloxane. Examples of silazanes include hexamethylsilazanes and tetramethylsilazanes. Siloxanes are preferred working gases, with tetramethyldisiloxane (TMDSO) being especially preferred.

As used herein, the term “balance gas” is a reactive or non-reactive gas that carries the working gas through the electrode and ultimately to the substrate. Examples of suitable balance gases include air, O₂, CO₂, NO, N₂O as well as combinations thereof. Oxygen (O₂) is a preferred balance gas.

In a first plasma polymerizing step, a first organosilicon compound is plasma polymerized in an oxygen rich atmosphere on the inner surface of the container, which may or may not be previously subjected to surface modification, for example, by roughening, crosslinking, or surface oxidation. As used herein, the term “oxygen-rich atmosphere” means that the balance gas contains at least about 20 percent (%) oxygen, more preferably at least about 50% oxygen. Thus, for the purposes of this invention, air is a suitable balance gas, but N₂ is not.

The quality of the polyorganosiloxane layer is virtually independent of the mole percent ratio of balance gas to the total gas mixture up to about 80 mole percent of the balance gas, at which point the quality of the layer degrades substantially. The power density of the plasma for the preparation of the polyorganosiloxane layer is preferably greater than 10 MJ/kg, more preferably greater than 20 MJ/kg, and most preferably greater than 30 MJ/kg; and preferably less than 1000 MJ/kg, more preferably less than 500 MJ/kg, and most preferably less than 300 MJ/kg.

In this first step after the pretreatment step, the plasma is sustained for preferably less than 5 seconds, more preferably less than 2 seconds, and most preferably less than 1 second; and preferably greater than 0.1 second, and more preferably greater than 0.2 second to form a polyorganosiloxane coating having a thickness of preferably less than 50 nanometer, more preferably less than 20 nanometer, and most preferably less than 10 nanometer; and preferably greater than 2.5 nanometer, more preferably greater than 5 nanometer (nm).

Preferably the first plasma polymerizing step is carried out at a deposition rate of less than about 50 nanometer/sec, more preferably less than 20 nanometer/sec, and preferably greater than 5 nanometer/sec, and more preferably greater than 10 nanometer/sec.

The preferred chemical composition of the polyorganosiloxane layer is SiOxCyHz, where x is in the range of 1.0 to 2.4, y is in the range of 0.2 to 2.4, and z is greater than or equal to 0, more preferably not more than 4.

In the second plasma polymerizing step, a second organosilicon compound, which may be the same as or different from the first organosilicon compound, is plasma polymerized to form a silicon oxide layer on the polyorganosiloxane layer described above, or a different polyorganosiloxane layer. In other words, it is possible, and sometimes advantageous, to have more than one polyorganosiloxane layer of different chemical compositions. Preferably, the silicon oxide layer is an SiOx layer, where x is in the range of 1.5 to 2.0.

For the second plasma polymerizing step, the mole ratio of balance gas to the total gas mixture is preferably about stoichiometric with respect to the balance gas and the worldng gas. For example, where the balance gas is oxygen and the working gas is TMDSO, the preferred mole ratio of balance gas to total gas is 85% to 95%. The power density of the plasma for the preparation of the silicon oxide layer is preferably greater than 10 MJ/kg, more preferably greater than 20 MJ/kg, and most preferably greater than 30 MJ/kg; and preferably less than 500 MJ/kg, and more preferably less than 300 MJ/kg.

In the second plasma polymerizing step, the plasma is sustained for preferably less than 10 seconds, and more preferably less than 5 seconds, and preferably greater than 1 second to form a silicon oxide coating having a thickness of less than 50 nm, more preferably less than 30 nm, and most preferably less than 20 nm, and preferably greater than 5 nm, more preferably greater than 10 nm.

Preferably, the second plasma polymerizing step is carried out at a deposition rate of less than about 50 nm/sec, more preferably less than 20 nm/sec, and preferably greater than 5.0 nm/sec, and more preferably greater than 10 nm/sec.

The total thickness of the first and second plasma polymerized layers is preferably less than 100 nm, more preferably less than 50 nm, more preferably less than 40 nm, and most preferably less than 30 nm, and preferably greater than 10 nm. The total plasma polymerizing deposition time (that is, the deposition time for the first and the second layers) is preferably less than 20 seconds, more preferably less than 10 seconds, and most preferably less than 5 seconds.

Surprisingly, it has been discovered that very thin and adherent coatings of uniform thickness can be rapidly deposited on the inner surface of a polyolefin container to create a barrier to the permeation of small molecules such O₂ and CO₂. As used herein, the word “uniform thickness” refers to a coating that has less than a 25% variance in thickness throughout the coated region. Preferably, the coating is virtually free of cracks or foramina. Preferably, the barrier improvement factor (BIF, which is the ratio of the transmission rate of a particular gas for the untreated bottle to the treated bottle) is at least 10, more preferably, at least 20.

The following example is for illustrative purposes only and is not intended to limit the scope of the invention.

### EXAMPLE 1

Preparation of a Polyorganosiloxane/Silicon Oxide Coating On a Polypropylene Bottle

An apparatus illustrated in FIG. 1 is used for this example. In this example, container 24 is a 500 mL polypropylene bottle suitable for carbonated beverages. Bottle 24 is inserted into tube 16, which is located in resonant cavity 12. Cover 12 is adapted with an open-ended graded porous injector 27 that is fitted into bottle 24 so that injector 27 extends to about 1 cm from the bottom of bottle 24. Injector 27 is fabricated by welding together three sections of 2.5″ long (6.3 cm) porous hollow stainless steel tubing (0.25″ outer diameter (0.64 cm), 0.16″ inner diameter (0.41 cm)), each tubing with a different porosity, to form a single 7.5″ (19 cm) graded injector as illustrated in FIG. 1. The top third of injector 27a has a pore size of about 20 μm, the middle third of the injector 27b has a pore size of about 30 μm, and the bottom third of the injector 27c has a pore size of about 50 μm. (Porous tubing available from Mott, Corp.)

A partial vacuum is established on both the inside and the outside of bottle 24. The outside of bottle 24 is maintained at 80 mbar and the inside is maintained initially at about 10 μbars. A pretreatment gas consisting essentially of O₂ is flowed through injector 27 at a flow rate of 100 sccm, at a pressure of 133 μbars, using a power of 500 watts for a time of 10 seconds.

An organosiloxane layer is deposited uniformly on the inside surface of the pretreated bottle 24 as follows. TMDSO and O₂ are each flowed together through injector 27 at the rate of 10 sccm, thereby increasing the partial pressure of the inside of the container. Once the partial pressure reaches 40 μbars (generally, less than 1 second), power is applied at 150 W (corresponding to a power density of 120 MJ/kg) for about 0.5 seconds to form an organosiloxane layer having a thickness of about 5 nm.

An SiOx layer is deposited uniformly over the organosiloxane layer as follows. TMDSO and O₂ are flowed together through injector 27 at rates of 10 sccm and 80 sccm, respectively, thereby increasing the partial pressure of the inside of bottle 24. Once the partial pressure reaches 60 μbars (generally, less than 1 second), power is applied at 350 W (corresponding to a power density of 120 MJ/kg) for about 3.0 seconds to form an SiOx layer having a thickness of about 15 nm.

Barrier performance is indicated by a barrier improvement factor (BIF), which denotes the ratio of the oxygen transmission rate of the uncoated extrusion blow molded polypropylene bottle to the coated bottle. The BIF is measured using an Oxtran 2/20 oxygen transmission device (available from Mocon, Inc.) to be 20, which corresponds to an oxygen transmission rate of 0.02 cm³/bottle/day.

Coating adhesion is indicated according to the ASTM D-3359 tape test. The adhesion of a polyorganosiloxane/silicon oxide coating on a polypropylene bottle is poor whereby greater than 65% of coating delaminates, which corresponds to a “0” according to the adhesion classification of the tape test. If the surface is first pretreated with an O₂ plasma prior to depositing the coating, the adhesion is excellent whereby none of the coating delaminates, which corresponds to a “5” according to the adhesion classification of the tape test.

### Another Embodiment

In another embodiment, the process of the present invention is advantageously, though not uniquely, carried out using the apparatus described in WO0066804, which is reproduced with some modification in FIG. 1. Again, container 24 is a container having at least an inner surface consisting essentially of polylactic acid or a polyolefin such as polypropylene. Coating of the container 24 can be accomplished by the following two steps. First an amorphous carbon layer is formed on the interior of the container 24 by flowing acetylene through injector 27 at a flow rate, for example and without limitation thereto, in the range of from to 1000 sccm, at a pressure in the range of 13 to 1333 μbars, using a power in the range of 20 to 2000 watts for a time less than one minute. Then gas or a mixture of gases such as Ar, He, H₂, O₂, N₂, air, CF₄, C₂F₆, CO₂, H₂O, O_{3, N}₂O and NO is flowed through injector 27 at a flow rate in the range of 10 to 1000 sccm, at a pressure in the range of 13 to 1333 μbars, using a power in the range of 20 to 2000 watts for a time less than one minute. Preferably, the gas is nitrogen. Preferably, the flow rate of the gas in either step is less than 500 sccm. More preferably, the flow rate of the gas in either step is less than 100 sccm. Preferably, the pressure of the gas in the container 24 in either step is less than 666 μbars. More preferably, the pressure of the gas in the container 24 in either step is less than 133 μbars. Preferably, the time of either step is less than 20 seconds. More preferably, time of either step is less than 2 seconds.

Although applicants are not held to such theory, it is theorized that the plasma of the second step of this second embodiment of the instant invention facilitates trapped free radicals in the amorphous carbon layer to bond at the interface. This promotes better adhesion of the amorphous carbon layer to the polypropylene container. Thus, alternatively, the interior surface of the coated container can be treated with the plasma generated as described above but generating the plasma on the outside of the container after the inside of the container has been coated with the amorphous carbon layer or at the same time that the inside of the container is being coated with amorphous carbon.

### EXAMPLE 2

Preparation of an Amorphous Carbon Coating on a Polypropylene Bottle

A partial vacuum is established on both the inside and the outside of bottle 24. The outside of bottle 24 is maintained at 80 mbar and the inside is maintained initially at about 10 μbars. A gas consisting essentially of acetylene is flowed through injector 27 at a flow rate of 160 sccm, at a pressure of 160 μbars, using a power of 300 watts for a time of 3 seconds. Then nitrogen is flowed through injector 27 at a flow rate in the range of 10 scam, at a pressure of 160 μbars, using a power of 100 watts for a time of ten seconds.

The amorphous carbon layer is adherent and has a thickness of about 150 nm. Barrier performance is indicated by a barrier improvement factor (BIF), which denotes the ratio of the oxygen transmission rate of the uncoated injection stretch blow molded polypropylene bottle to the coated bottle. The BIF is measured using an Oxtran 2/20 oxygen transmission device (available from Mocon, Inc.) to be 40, which corresponds to an oxygen transmission rate of about 0.009 cm³/bottle/day.

Coating adhesion is indicated according to the ASTM D-3359 tape test. The adhesion of an amorphous carbon coating on a polypropylene bottle is poor whereby greater than 65% of coating delaminates, which corresponds to a “0” according to the adhesion classification of the tape test. If the surface is first pretreated with and O₂ plasma prior to depositing the coating, the adhesion is excellent whereby none of the coating delaminates, which corresponds to a “5” according to the adhesion classification of the tape test.

1. An improved process for preparing a protective barrier for a container including the step of plasma coating the interior of the container with a plasma polymerized coating, wherein the improvement comprises the step of pretreating the interior surface of a polyolefin or a polylactic acid container with a plasma for less than one minute.

2. The process of claim 1, wherein the plasma is generated by microwave energy in the range of 20 to 2000 watts in a gas consisting essentially of Ar, He, H₂, O₂, N₂, air, CF₄, C₂F₆, CO₂, H₂O, O₃, N₂0 and NO or mixtures thereof at a pressure in the range of 10 to 1333 μbars.

3. The process of claim 1, wherein the gas consists essentially of oxygen.

4. An improved process for preparing a protective barrier for a container including the step of plasma coating the interior of the container with a plasma induced coating of amorphous carbon, wherein the improvement comprises the step of treating the interior surface of the coated container with a plasma for less than one minute, the container being a polyolefin container or a polylactic acid container.

5. The process of claim 4, wherein the plasma is generated by microwave energy in the range of 20 to 2000 watts in a gas consisting essentially of Ar, He, H₂, O₂, N₂, air, CF₄, C₂F₆, CO₂, H₂O, O₃, N₂O and NO or mixtures thereof at a pressure in the range of 10 to 1333 μbars.

6. The process of claim 5, wherein the gas consists essentially of nitrogen.

7. The process of any of claims 1-6, wherein the container is a polypropylene container.
